(19) United States
(12) Patent Application Publication
(10) Pub. No.: US 2013/0307026 A1
(43) Pub. Date: Nov. 21, 2013

(54) HIGH ELECTRON MOBILITY TRANSISTORS AND METHODS OF MANUFACTURING THE SAME

(71) Applicant: SAMSUNG ELECTRONICS CO., LTD., Suwon-Si (KR)

(72) Inventors: Sun-kyu HWANG, Seoul (KR); Jai-kwang SHIN, Anyang-si (KR); Hyuk-soon CHOI, Hwaseong-si (KR); Jong-seob KIM, Hwaseong-si (KR); Jae-joon OH, Seongnam-si (KR); Jong-bong HA, Yongin-si (KR); In-jun HWANG, Hwaseong-si (KR); Kyoung-yeon KIM, Seongnam-si (KR)

(73) Assignee: SAMSUNG ELECTRONICS CO., LTD., Suwon-Si (KR)

(21) Appl. No.: 13/752,766

(22) Filed: Jan. 29, 2013

(30) Foreign Application Priority Data
May 16, 2012 (KR) 10-2012-0052213

(51) Int. Cl. H01L 29/778; H01L 29/66

(52) U.S. Cl. CPC H01L 29/778; H01L 29/66431
USPC 257/194; 438/172

(57) ABSTRACT

According to example embodiments, High electron mobility transistors (HEMTs) may include a discontinuation region in a channel region. The discontinuation region may include a plurality of 2DEG unit regions that are spaced apart from one another. The discontinuation region may be formed at an interface between two semiconductor layers or adjacent to the interface. The discontinuation region may be formed by an uneven structure or a plurality of recess regions or a plurality of ion implantation regions. The plurality of 2DEG unit regions may have a nanoscale structure. The plurality of 2DEG unit regions may be formed in a dot pattern, a stripe pattern, or a staggered pattern.

### CROSS-REFERENCE TO RELATED APPLICATION

This application claims priority under 35 U.S.C. §119 to Korean Patent Application No. 10-2012-0052213, filed on May 16, 2012, in the Korean Intellectual Property Office, the disclosure of which is incorporated herein in its entirety by reference.

### BACKGROUND

1. Field

Example embodiments relate to semiconductor devices and/or methods of manufacturing the same, and more particularly, to high electron mobility transistors (HEMTs) and/or methods of manufacturing the HEMTs.

2. Description of the Related Art

High electron mobility transistors (HEMTs) may include semiconductors with different electric polarization characteristics. In a HEMT, a semiconductor layer having relatively high polarizability may induce a 2-dimensional electron gas (2DEG) in another semiconductor layer adhered to the semiconductor layer. Electron mobility in the 2DEG may be very high. The 2DEG may be used as a channel of the HEMT.

Improving or adjusting the characteristics of a HEMT may be done to efficiently use the HEMT in various electronic devices. In particular, a threshold voltage, an on-current level, and the like of the HEMT may be improved or adjusted.

### SUMMARY

Example embodiments relate to high electron mobility transistors (HEMTs) having excellent operating characteristics.

Example embodiments relate to HEMTs having a normally-off characteristic and a low channel resistance.

Example embodiments relate to enhancement-mode (E-mode) HEMTs having a low on-resistance.

Example embodiments relate to methods of manufacturing HEMTs.

Additional aspects will be set forth in part in the description which follows and, in part, will be apparent from the description, or may be learned by practice of example embodiments.

According to example embodiments, a high electron mobility transistor (HEMT) includes: a first semiconductor layer; a second semiconductor layer on the first semiconductor layer, the second semiconductor layer being configured to induce a 2-dimensional electron gas (2DEG) in the first semiconductor layer; a gate corresponding to a discontinuation region of the first semiconductor layer in which a plurality of 2DEG unit regions are spaced apart from one another; and a source and a drain spaced apart from the gate. The source and drain are electrically connected to the 2DEG.

In example embodiments, the discontinuation region of the first semiconductor layer may be defined by an uneven portion in the first semiconductor layer that is under the gate.

In example embodiments, the uneven portion may be defined by a plurality of protrusions and depressions formed between the protrusions along an upper surface of the first semiconductor layer, and the second semiconductor layer may cover the plurality of protrusions and the plurality of depressions.

In example embodiments, the second semiconductor layer may be configured to induce the plurality of 2DEG unit regions in the plurality of protrusions.

In example embodiments, the second semiconductor layer may be configured to induce the plurality of 2DEG unit regions in the first semiconductor layer corresponding to the plurality of depressions.

In example embodiments, the discontinuation region of the first semiconductor layer may be defined by a plurality of recess regions formed in the second semiconductor layer corresponding to the gate.

In example embodiments, the plurality of recess regions in the second semiconductor layer may extend into the first semiconductor layer.

In example embodiments, the plurality of recess regions in the second semiconductor layer may extend to an interface between the first and second semiconductor layers, or the plurality of recess regions in the second semiconductor layer may extend to a depth that is shallower than the interface between the first and second semiconductor layers.

In example embodiments, an insulating layer may fill the plurality of recess regions in the second semiconductor layer, and the gate may be on the insulating layer.

In example embodiments, the HEMT may further include: the discontinuation region of the first semiconductor layer may be defined by a plurality of ion implantation regions formed in the second semiconductor layer corresponding to the gate.

In example embodiments, the plurality of ion implantation regions may extend inside the first semiconductor layer.

In example embodiments, the plurality of ion implantation regions may extend to an interface between the first and second semiconductor layers, or the plurality of ion implantation regions may extend to a depth of the second semiconductor layer that is shallower than the interface between the first and second semiconductor layers.

In example embodiments, the plurality of ion implantation regions may be amorphous regions.

In example embodiments, the second semiconductor layer may be a contiguous layer.

In example embodiments, the plurality of 2DEG unit regions may be formed in a dot pattern.

In example embodiments, the plurality of 2DEG unit regions may be formed in a stripe pattern.

In example embodiments, the plurality of 2DEG unit regions may have a width from about tens of nanometers to about hundreds of nanometers.

In example embodiments, a gap between the plurality of 2DEG unit regions may be in a range of about several nanometers to about hundreds of nanometers.

In example embodiments, the first semiconductor layer may contain a gallium nitride (GaN)-based material.

In example embodiments, the second semiconductor layer may include one of a single-layered structure and a multi-layered structure, and the second semiconductor layer may include a nitride that contains at least one of aluminum (Al), gallium (Ga), indium (In), and boron (B).

In example embodiments, the HEMT may be configured as a normally-off device.

In example embodiments, the HEMT may be used as a power device.

According to example embodiments, a method of manufacturing a high electron mobility transistor (HEMT) includes: forming a first semiconductor layer; forming an uneven portion in the first semiconductor layer for defining a discontinuation region of the first semiconductor layer; forming a second semiconductor layer on the first semiconductor layer, the second semiconductor layer being configured to induced a 2DEG in the first semiconductor layer and a plurality of 2DEG unit regions in the discontinuation region of the first semiconductor layer; forming a gate on the second semiconductor layer and the discontinuation region of the first semiconductor layer; and forming a source and a drain that are spaced apart from the gate.

In example embodiments, forming the uneven portion may include forming a self-assembled monolayer (SAM) as an etch mask on the first semiconductor layer.

In example embodiments, forming the uneven portion may include forming an etch mask obtained by anodization on the first semiconductor layer.

In example embodiments, forming the uneven portion may include forming an etch mask on the first semiconductor layer by a nanoimprinting process.

The plurality of 2DEGs may be formed into a dot pattern.

The plurality of 2DEGs may be formed in a stripe pattern.

In example embodiments, the first semiconductor layer may include a GaN-based material.

In example embodiments, the second semiconductor layer may include one of a single-layered structure and a multi-layered structure, and the second semiconductor layer may contain a nitride that includes at least one of Al, Ga, In, and B.

According to example embodiments, a method of manufacturing a high electron mobility transistor (HEMT) includes: forming a first semiconductor layer; forming a second semiconductor layer on the first semiconductor layer, the second semiconductor layer being configured to induce a 2DEG in the first semiconductor layer; forming a plurality of recess regions recessed from a region of the second semiconductor layer to a region of the first semiconductor layer, the recess regions forming a discontinuation region where a plurality of 2DEG unit regions are spaced apart from one another; forming a gate on the second semiconductor layer and the discontinuation region of the first semiconductor layer; and forming a source and a drain that are spaced apart from the gate.

In example embodiments, an insulating layer may be formed on the second semiconductor layer to fill the plurality of recess regions, and the gate may be formed on the insulating layer.

In example embodiments, the plurality of 2DEGs may be formed in a dot pattern.

In example embodiments, the plurality of 2DEGs may be formed in a stripe pattern.

In example embodiments, the first semiconductor layer may include a GaN-based material.

In example embodiments, the second semiconductor layer may include one of a single-layered structure and a multi-layered structure, and the second semiconductor layer may include a nitride that contains at least one of Al, Ga, In, and B.

According to example embodiments, a method of manufacturing a high electron mobility transistor (HEMT) includes: forming a first semiconductor layer; forming a second semiconductor layer on the first semiconductor layer, the second semiconductor layer being configured to induce a 2DEG in the first semiconductor layer; forming a plurality of ion implantation regions extending from a region of the second semiconductor layer to a region of the first semiconductor layer, the plurality of ion implantation regions forming a discontinuation region in the first semiconductor layer where a plurality of 2DEG unit regions are spaced apart from one another; forming a gate on the second semiconductor layer and the discontinuation region of the first semiconductor layer; and forming a source and a drain that are spaced apart from the gate.

In example embodiments, the plurality of ion implantation regions may be amorphous regions.

In example embodiments, the plurality of 2DEGs may be formed in a dot pattern.

In example embodiments, the plurality of 2DEGs may be formed in a stripe pattern.

In example embodiments, the first semiconductor layer may contain a GaN-based material.

In example embodiments, the second semiconductor layer may include one of a single-layered structure and a multi-layered structure, and the second semiconductor layer may contain a nitride that includes at least one of Al, Ga, In, and B.

According to example embodiments, a high electron mobility transistor (HEMT) may include: a first semiconductor layer; a source, a gate, and a drain spaced apart on the first semiconductor layer; and a second semiconductor layer between the gate and the first semiconductor layer. The second semiconductor layer may be a contiguous layer having a different polarization than a polarization of the first semiconductor layer. The second semiconductor layer may include one of a plurality of openings defined by the second semiconductor layer, a plurality of grooves defined by the second semiconductor layer, and a plurality of ion implant regions between the gate and the first semiconductor layer. The second semiconductor layer may be configured to induce a plurality of 2DEG unit regions in the first semiconductor layer that are spaced apart from each other.

In example embodiments, the second semiconductor layer may include the plurality of openings, the plurality of openings defined by the second semiconductor layer may expose a plurality of portions of the first semiconductor layer that are between the plurality of 2DEG unit regions of the first semiconductor layer from a plan view.

In example embodiments, an uneven portion of the first semiconductor layer may define a plurality of protrusions and a plurality of depressions along an upper surface of the first semiconductor layer, and the second semiconductor layer may be between the gate and the uneven portion of the first semiconductor layer.

In example embodiments, the second semiconductor layer may include the plurality of ion implant regions.

In example embodiments, the plurality of 2DEG unit regions may be formed in one of a dot pattern and a stripe pattern. In example embodiments, the first semiconductor layer may include a GaN-based material. In example embodiments, the second semiconductor layer may include one of a single-layered structure and a multi-layered structure, and the second semiconductor layer may contain a nitride that includes at least one of Al, Ga, In, and B.

### BRIEF DESCRIPTION OF THE DRAWINGS

The foregoing and other features and advantages of example embodiments will become apparent and more readily appreciated from the following description of non-limiting embodiments, as illustrated in the accompanying drawings in which like reference characters refer to the same parts throughout the different views. The drawings are not necessarily to scale, emphasis instead being placed upon illustrating the principles of example embodiments. In the drawings:

FIG. 1 is a cross-sectional diagram illustrating a high electron mobility transistor (HEMT) according to example embodiments;

FIGS. 2A to 2C are plan views of main elements of the HEMT of FIG. 1, according to example embodiments;

FIG. 3 is a cross-sectional diagram illustrating a HEMT according to example embodiments;

FIG. 4 is a cross-sectional diagram illustrating a HEMT according to example embodiments;

FIG. 5 is a cross-sectional diagram illustrating a HEMT according to example embodiments;

FIG. 6 is a cross-sectional diagram illustrating a HEMT according to example embodiments;

FIG. 7 is a cross-sectional diagram illustrating a HEMT according to example embodiments;

FIG. 8 is a cross-sectional diagram illustrating a HEMT according to example embodiments;

FIG. 9 is a cross-sectional diagram illustrating a HEMT according to example embodiments;

FIGS. 10A through 10E are cross-sectional diagrams sequentially illustrating a method of manufacturing a HEMT, according to example embodiments;

FIGS. 11A through 11C are cross-sectional diagrams sequentially illustrating a method of manufacturing a HEMT, according to example embodiments;

FIGS. 12A through 12D are cross-sectional diagrams sequentially illustrating a method of manufacturing a HEMT, according to example embodiments;

FIG. 13 is a graph showing voltage-current characteristics of HEMTs manufactured according to Example 1 and Comparative Example;

FIG. 14 is a cross-sectional diagram illustrating a structure of the HEMT according to Example 1 of FIG. 13; and

FIG. 15 is a cross-sectional diagram illustrating a structure of the HEMT according to the Comparative Example of FIG. 13.

### DETAILED DESCRIPTION

Example embodiments will now be described more fully with reference to the accompanying drawings, in which some example embodiments are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description may be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” when used in this specification, specify the presence of stated features, integers, steps, operations, elements, and/or components, but do not preclude the presence or addition of one or more other features, integers, steps, operations, elements, components, and/or groups thereof. Expressions such as “at least one of,” when preceding a list of elements, modify the entire list of elements and do not modify the individual elements of the list.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

Hereinafter, example embodiments of a high electron mobility transistor (HEMT) and a method of manufacturing the HEMT will be described in detail with reference to the accompanying drawings. In the drawings, the widths and thicknesses of layers and regions are exaggerated for clarity. Like reference numerals in the drawings denote like elements.

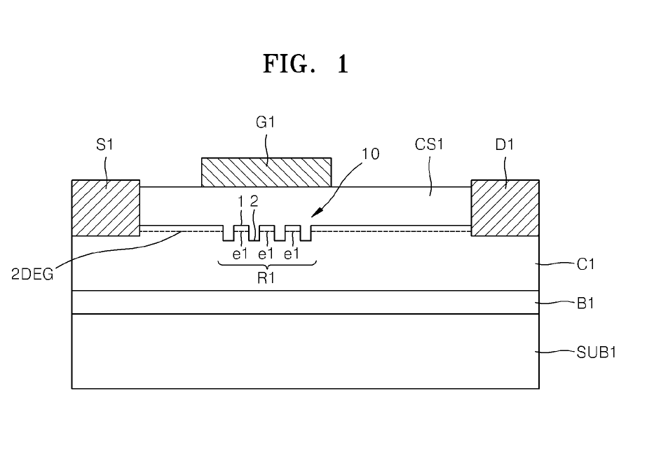

FIG. 1 is a cross-sectional diagram illustrating a HEMT according to example embodiments.

Referring to FIG. 1, a buffer layer B1 may be disposed on a substrate SUB1. The substrate SUB1 may include, for example, sapphire, silicon (Si), silicon carbide (SiC), gallium nitride (GaN), or the like. The buffer layer B1 may reduce differences in lattice constant and thermal expansion coefficient between the substrate SUB1 and a channel layer C1. The buffer layer B1 may reduce (and/or prevent) deterioration of crystallinity of the channel layer C1. The buffer layer B1 may have a single-layered or multi-layered structure including at least one material selected from nitrides containing at least one of aluminum (Al), gallium (Ga), indium (In), and boron (B). In particular, the buffer layer B1 may have a single-layered or multi-layered structure including at least one of various material selected from aluminum nitride (AlN), gallium nitride (GaN), aluminum gallium nitride (AlGaN), indium gallium nitride (InGaN), aluminum indium nitride (AlInN), and aluminum gallium indium nitride (AlGaInN). In some cases, a seed layer (not shown) may be disposed between the substrate SUB1 and the buffer layer B1. The seed layer may be a base layer for growing the buffer layer B1.

The channel layer C1 may be disposed on the buffer layer B1. The channel layer C1 may be a semiconductor layer. The channel layer C1 may include a Group III-V based compound semiconductor. For example, the channel layer C1 may include a GaN-based material (e.g., GaN). In this case, the channel layer C1 may be an undoped GaN layer, but in some cases, may be a GaN layer doped with one or more impurities. A channel supply layer CS1 may be disposed on the channel layer C1. The channel supply layer CS1 may be a different semiconductor layer from the channel layer C1. The channel supply layer CS1 may be a layer for supplying a 2-dimensional electron gas (2DEG) to the channel layer C1. The 2DEG may be induced in a region of the channel layer C1 adjacent to the interface between the channel layer C1 and the channel supply layer CS1. The channel supply layer CS1 may include a material with different polarization characteristic and/or energy bandgap and/or lattice constant from those of the channel layer C1. For example, the channel supply layer CS1 may include a material (semiconductor) with higher polarizability and/or wider energy bandgap than those of the channel layer C1. For example, the channel supply layer CS1 may have a single-layered or multi-layered structure including at least one material selected from nitrides containing at least one of Al, Ga, In, and B. In particular, the channel supply layer CS1 may have a single-layered or multi-layered structure including at least one of various materials selected from AlGaN, AlInN, InGaN, AlN, AlInGaN, and the like. The channel supply layer CS1 may be an undoped layer, or may be a layer doped with one or more impurities. The channel supply layer CS1 may have a thickness of several tens of nanometers or less. For example, the thickness of the channel supply layer CS1 may be about 50 nm or less.

A gate electrode G1 may be disposed on a portion of the channel supply layer CS1. The gate electrode G1 may form a Schottky contact with the channel supply layer CS1. The gate electrode G1 may include a material (e.g., a metal, a metal compound, and the like) that forms a Schottky contact with the channel supply layer CS1. In example embodiments, a Schottky contact layer (not shown) may be formed between the gate electrode G1 and the channel supply layer CS1. However, example embodiments are not limited thereto and in some cases, the gate electrode G1 may not form a Schottky contact with the channel supply layer CS1.

A source electrode S1 and a drain electrode D1 may be disposed at both sides of the gate electrode C1. The source S1 and drain D1 may be connected to ends of the channel supply layer CS1, and the channel supply layer CS1 may be a contiguous layer between the source S1 and drain D1. The source and drain electrodes S1 and D1 may be electrically connected to the 2DEG. For example, after the channel supply layer CS1 and the channel layer C1 are partially etched (recessed), the source electrode S1 and the drain electrode D1 may be formed on the etched regions (recess regions). In this regard, the depth of the etched region (recess region) may be larger than that of the 2DEG. Thus, the source and drain electrodes S1 and D1 may directly contact side portions of the 2DEG, but are not limited thereto. In example embodiments, the source and drain electrodes S1 and D1 may be formed only after the channel supply layer CS1 is partially etched, or the source and drain electrodes S1 and D1 may be formed on the channel supply layer CS1 without an etching process. The source electrode S1 may be positioned closer to the gate electrode G1 than the drain electrode D1. That is, a distance between the source electrode S1 and the gate electrode G1 may be less than a distance between the drain electrode D1 and the gate electrode G1. However, relative distances between the source electrode S1 and the gate electrode G1 and between the drain electrode D1 and the gate electrode G1 may vary.

A region of the 2DEG that corresponds to the gate electrode G1 may include a discontinuation region R1. The discontinuation region R1 may include a plurality of 2DEG unit regions e1 that are spaced apart from one another. The plurality of 2DEG unit regions e1 may have a nanoscale structure. For example, each 2DEG unit region e1 may have a width of about tens of nanometers to about hundreds of nanometers. A gap between the 2DEG unit regions e1 may be about several nanometers to about hundreds of nanometers. The width and gap ranges are provided for illustrative purposes only, and the width and gap ranges may vary if desired. For example, the width of the 2DEG unit region e1 may be greater than several hundreds of nanometers, and the gap therebetween may also be greater than several hundreds of nanometers. The discontinuation region R1 may be referred to as a region in which the 2DEG is patterned, i.e., a “patterned 2DEG region.”

The discontinuation region R1 including the plurality of 2DEG unit regions e1 spaced apart from one another may be formed by an uneven portion 10 disposed at the interface between the channel layer C1 and the channel supply layer CS1. The uneven portion 10 may be formed in a region of the channel layer C1 that corresponds to the gate electrode G1. The uneven portion 10 may include a plurality of protrusions 1 and depressions 2 respectively formed between the protrusions 1. The channel supply layer CS1 may cover the protrusions 1 and the depressions 2. The channel supply layer CS1 may define grooves in which the protrusions 1 are disposed. Each 2DEG unit region e1 may be formed in the protrusion 1. The 2DEG may not be formed in the depressions 2. The depressions 2 may be formed by etching. In this regard, when the channel layer C1 is damaged by the etching process, the crystallinity of the channel layer C1 is changed, and thus, the 2DEG may not be formed in the depressions 2. In some cases, however, the 2DEG may be formed on a lower surface portion of the depression 2. In this case, the 2DEG may not be formed on side surfaces of the depression 2.

A threshold voltage of the HEMT may be increased by the discontinuation region R1 of the 2DEG corresponding to the gate electrode G1. That is, since the 2DEG is discontinuously formed, the threshold voltage of the HEMT may be increased. In this regard, the HEMT may be a normally-off device having a threshold voltage of greater than 0 V. Also, the HEMT may be an enhancement mode (E-mode) device. In a region of the 2DEG corresponding to the gate electrode G1, e.g., the discontinuation region R1, the plurality of 2DEG unit regions e1 are adjacent to one another, and thus, the 2DEG unit regions e1 of the discontinuation region R1 may exhibit high electrical conductivity in a turned-on state, and thus, an on-resistance of the HEMT may decrease and an on-current of the HEMT may increase. In other words, when a bias voltage is applied to the gate electrode G1 (a turned-on state), electrons are filled between the 2DEG unit regions e1 and a current may flow through the discontinuation region R1. In this operation, the 2DEG unit regions e1 may act as an excellent electric conductor. Accordingly, the on-resistance of the HEMT may decrease and the on-current of the HEMT may increase. Therefore, according to example embodiments, a HEMT having normally-off characteristics and a low channel resistance may be obtained. In other words, an E-mode HEMT having a low on-resistance may be obtained.

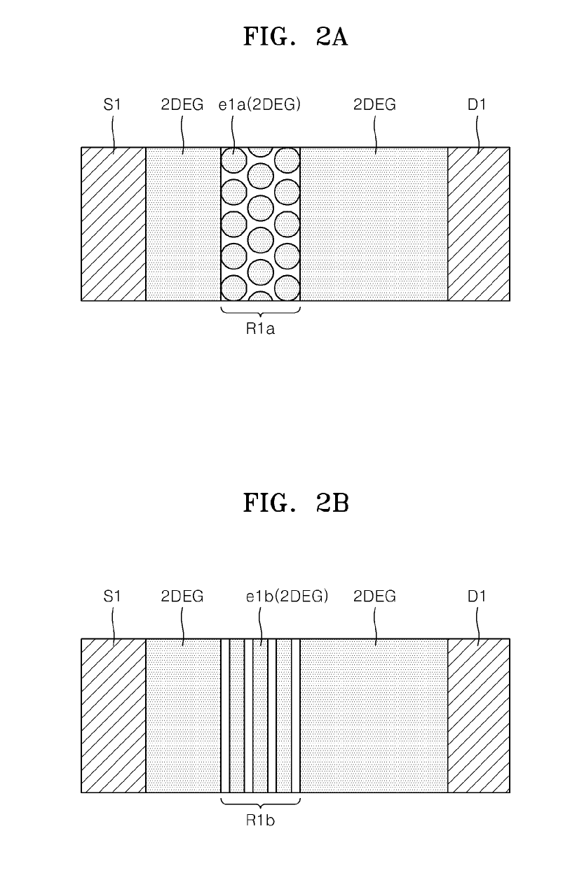

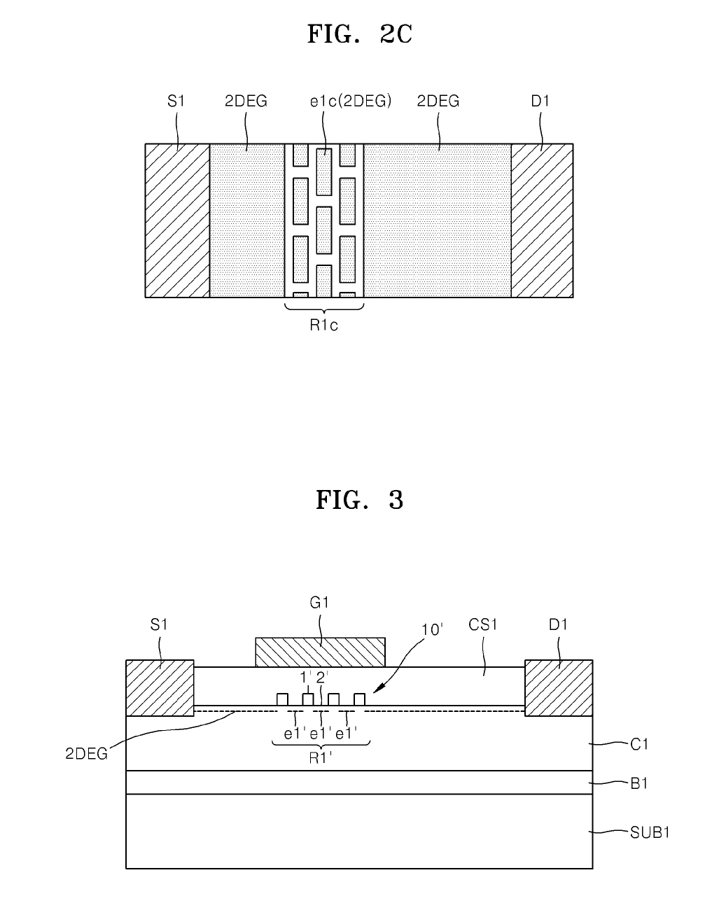

FIGS. 2A to 2C are plan views of main elements of the HEMT of FIG. 1, according to example embodiments.

Referring to FIG. 2A, the 2DEG is formed between the source electrode S1 and the drain electrode D1, and the discontinuation region R1a may correspond to the discontinuation region R1 illustrated in FIG. 1. The discontinuation region R1a may be formed in a region of the 2DEG corresponding to the gate electrode G1 (refer to FIG. 1). The discontinuation region R1a may be a region in which the plurality of 2DEG unit regions e1a are spaced apart from one another. In example embodiments, the plurality of 2DEG unit regions e1a may be formed in a dot pattern. Each 2DEG unit region e1a may have a spherical shape or a shape similar thereto. Each 2DEG unit region e1a may have a width (diameter) of about tens of nanometers to about hundreds of nanometers, and a distance therebetween may be about several nanometers to about hundreds of nanometers. In example embodiments, the width and distance may be greater than several hundreds of nanometers. For example, each 2DEG unit region e1a may have a width of about 10 nm to about 900 nm, about 30 nm to about 800 nm, and/or about 50 nm to about 500 nm, but example embodiments are not limited thereto. For example, a gap between the 2DEG unit regions e1a may be about 5 nm to about 500 nm, and/or about 10 nm to about 300 nm.

Referring to FIG. 2B, the 2DEG is formed between the source electrode S1 and the drain electrode D1, and the discontinuation region R1b may correspond to the discontinuation region R1 illustrated in FIG. 1. As shown in FIG. 2B, the plurality of 2DEG unit regions e1b may be formed in a stripe pattern. In this regard, the 2DEG unit regions e1b may have a line shape extending in a width direction of the channel. In addition, the 2DEG unit regions e1b may be spaced apart from one another in a length direction of the channel. Each 2DEG unit region e1b may have a width of about tens of nanometers to about hundreds of nanometers, and a distance therebetween may be about several nanometers to about hundreds of nanometers. In example embodiments, the width and distance may be greater than several hundreds of nanometers. For example, each 2DEG unit region e1b may have a width of about 10 nm to about 900 nm, about 30 nm to about 800 nm, and/or about 50 nm to about 500 nm, but example embodiments are not limited thereto. For example, a gap between the 2DEG unit regions e1b may be about 5 nm to about 500 nm, and/or about 10 nm to about 300 nm.

Referring to FIG. 2C, the 2DEG is formed between the source electrode S1 and the drain electrode D1, and the discontinuation region R1c may correspond to the discontinuation region R1 illustrated in FIG. 1. As shown in FIG. 2C, the plurality of 2DEG unit regions e1c may be formed in a staggered pattern. In this regard, the 2DEG unit regions e1c may have a line shape extending in a width direction of the channel. However, a width of the unit regions e1c may be less than a total width of the channel. In addition, the 2DEG unit regions e1c may be spaced apart from one another in a length direction of the channel and offset from each other. Each 2DEG unit region e1c may have a width of about tens of nanometers to about hundreds of nanometers, and a distance therebetween may be about several nanometers to about hundreds of nanometers. In example embodiments, the width and distance may be greater than several hundreds of nanometers. For example, each 2DEG unit region e1c may have a width of about 10 nm to about 900 nm, about 30 nm to about 800 nm, and/or about 50 nm to about 500 nm, but example embodiments are not limited thereto. For example, a gap between the 2DEG unit regions e1c may be about 5 nm to about 500 nm, and/or about 10 nm to about 300 nm. Examples of the pattern of the discontinuation region R1 are illustrated in FIGS. 1, 2A 2B, and 2C, the discontinuation regions R1, R1a, R1b, and R1C may have various types of the pattern.

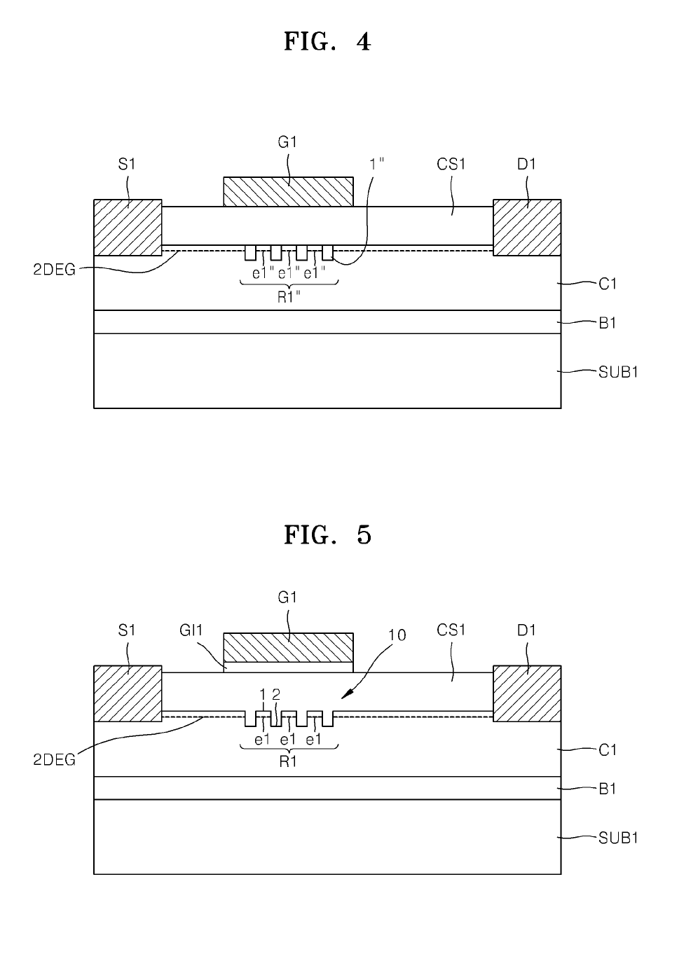

The uneven portion 10 of FIG. 1 may be modified in various ways. Another example of the uneven portion 10 of FIG. 1 is illustrated in FIGS. 3 and 4.

Referring to FIG. 3, an uneven portion 10′ may include a plurality of protrusions 1′ on a top surface of the channel layer C1. The plurality of protrusions 1′ may be formed of a different material than that of the channel layer C1. For example, the protrusions 1′ may be formed of an insulating material or a different semiconductor material than that of the channel layer C1. Regions between the protrusions 1′ may be denoted as depressions 2′. The channel supply layer CS1 may be formed on the channel layer C1 to cover the protrusions 1′ and the depressions 2′. Each of a plurality of 2DEG unit regions e1's may be disposed between regions of the channel layer C1 corresponding to the protrusions 1′. That is, each 2DEG unit region e1′ may correspond to the depression 2′. A discontinuation region R1′ may be formed by the plurality of 2DEG unit regions e1′ that are spaced apart from one another. The channel supply layer CS1 may define grooves in which the protrusions 1′ are disposed.

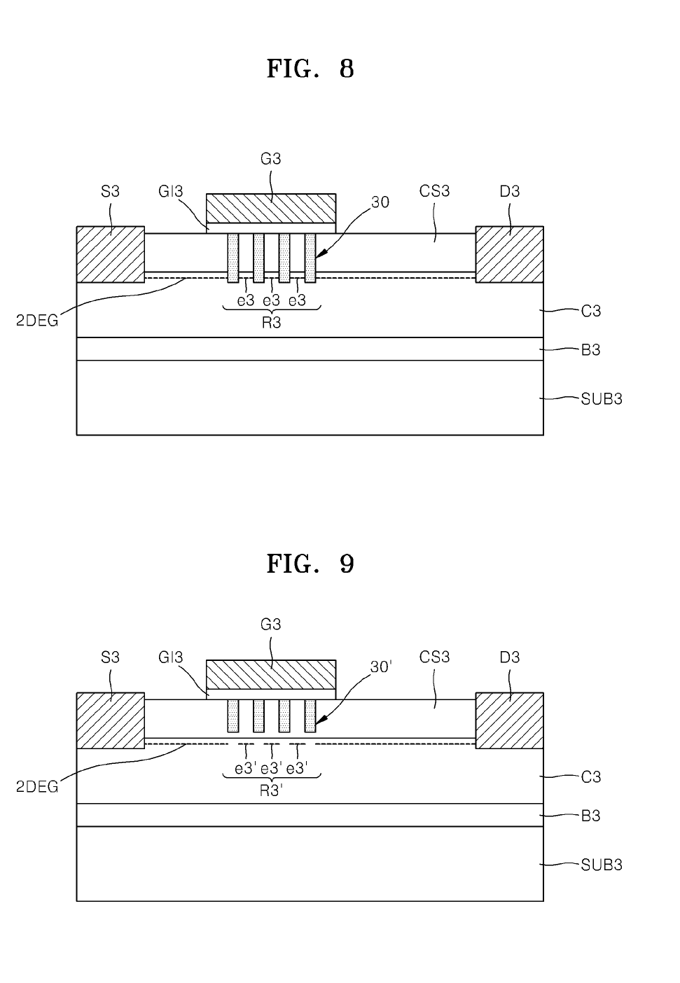

Referring to FIG. 4, an HEMT according to example embodiments is illustrated where a plurality of structures 1″ containing a different material than the channel layer C1 are disposed in grooves defined by the channel layer C1. The grooves defined by the channel layer are between the channel layer C1 and the channel supply layer CS1. The structure 1″ may contain an insulating material, or a different semiconductor material than that of the channel layer C1. For example, the structure 1″ may contain an amorphous semiconductor. However, example embodiments are not limited thereto. For example, the plurality of structures 1″ may be ion implant regions formed in the channel layer C1 instead of being a different material disposed in grooves defined by the channel layer. FIGS. 8-9 also describe HEMTs according to example embodiments that include ion implant regions 30 and 30′.

Although not shown in FIGS. 3-4, an HEMT according to example embodiments may also include both the protrusions 1′ in FIG. 3 and the structure 1″ in FIG. 4, such that the protrusions 1′ and structure 1″ contact each other.

The HEMTs of FIGS. 1 and 2A to 2C may be modified in various ways. For example, as illustrated in FIG. 5, according to example embodiments, a gate insulating layer may be disposed between the channel supply layer CS1 and the gate electrode G1. Referring to FIG. 5, a gate insulating layer GI1 may be disposed between the gate electrode G1 and the channel supply layer CS1. The gate insulating layer GI1 may be between the gate electrode G1 and the channel supply layer CS1, extending up to the source electrode 51 and the drain electrode D1. The gate insulating layer GI1 may include at least one of Al2O3, SiOx, SixNy, Sc2O3, AlN, Ga2O3, Gd2O3, AlxGa2(1−x)O3, MgO, and combinations thereof. According to example embodiments, the gate insulating layer GI1 may include any material for forming a gate insulating layer that is used in a general transistor. When the gate insulating layer GI1 is used, the gate electrode G1 does not need to form a Schottky contact with the channel supply layer CS1, and thus, more various materials may be used for forming the gate electrode G1 than in the case where the Schottky contact is used between the gate electrode G1 and the channel supply layer CS1. In addition, the gate electrode G1 and the source and drain electrodes S1 and D1 may be formed of the same material.

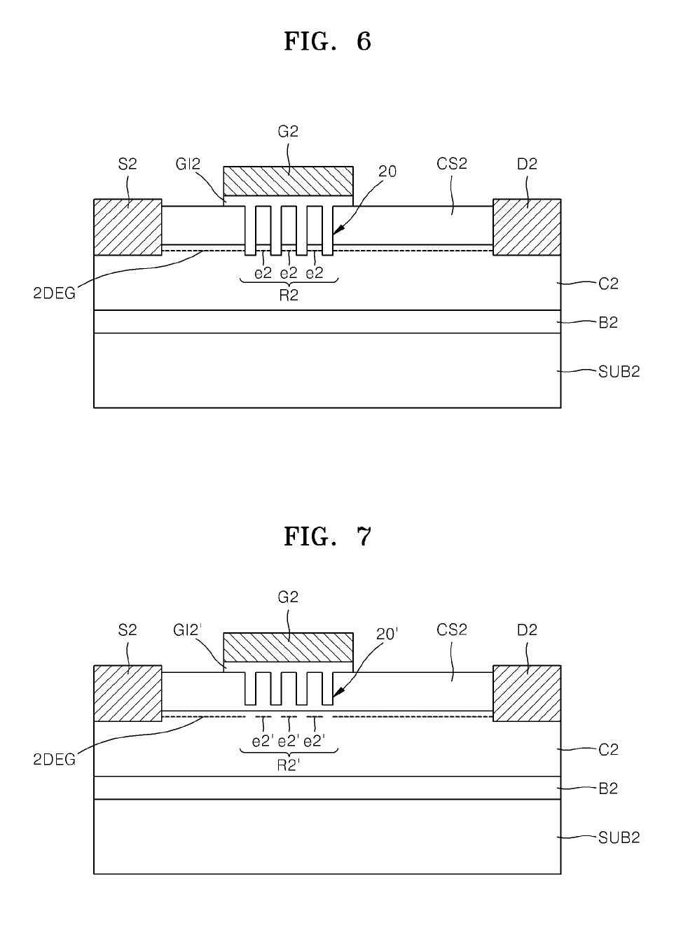

FIG. 6 is a cross-sectional diagram illustrating a HEMT according to example embodiments.

Referring to FIG. 6, a discontinuation region R2 may be disposed in a region of a 2DEG corresponding to a gate electrode G2. The discontinuation region R2 may be formed by a plurality of recess regions 20. The plurality of recess regions 20 may be regions recessed from a region of a channel supply layer CS2 towards a region of a channel layer C2 contacting the channel supply layer CS2. The recess regions 20 may extend up to the inside of the channel layer C2. The recess regions 20 may be a plurality of openings defined by the channel supply layer CS2 that expose the channel C2. The 2DEG may not be formed in portions where the recess regions 20 are formed, and each of a plurality of 2DEG unit regions e2 may be formed between the recess regions 20. The plurality of 2DEG unit regions e2 may have a pattern structure of the discontinuation region R1 as illustrated in FIG. 2A to 2C. A gate insulating layer GI2 may be formed on the channel supply layer CS2 to cover the plurality of recess regions 20, and a gate electrode G2 may be formed on the gate insulating layer GI2.

In FIG. 6, the gate insulating layer GI2 is formed on the channel supply layer CS2. In example embodiments, however, the gate insulating layer GI2 may be formed only inside the plurality of recess regions 20, and the gate electrode G2 may be formed on the gate insulating layer GI2 and a region of the channel supply layer CS2 that is around the gate insulating layer GI2. In example embodiments, the gate insulating layer GI2 may not be formed, and the gate electrode G2 may be formed on a region in which the plurality of recess regions 20 are formed. In this case, the plurality of recess regions 20 may not be filled by the gate electrode G2, and may be maintained empty (e.g., void). Materials and properties of a substrate SUB2, a buffer layer B2, the channel layer C2, the channel supply layer CS2, a source electrode S2, and a drain electrode D2 of the HEMT of FIG. 6 may be the same as or similar to those of the substrate SUB1, the buffer layer B1, the channel layer C1, the channel supply layer CS1, the source electrode S1, and the drain electrode D1 of the HEMT of FIG. 1.

The plurality of recess regions 20 of FIG. 6 may be formed to a different depth. The recess regions 20 may be formed to an interface between the channel layer C2 and the channel supply layer CS2, or to a smaller depth than that of the interface. A case where the recess regions 20 are formed to a smaller depth than that of the interface is illustrated in FIG. 7.

Referring to FIG. 7, a plurality of recess regions 20′ may be formed to a smaller depth than that of the channel supply layer CS2. That is, the recess regions 20′ may not be formed to the inside of the channel layer C2, and be formed only in the channel supply layer CS2. For example, the recess regions 20′ may be grooves defined in the channel supply layer CS2. Even in this case, properties of regions of a 2DEG that respectively correspond to the recess regions 20′ vary, and thus, a discontinuation region R2′ may be formed in the region of the 2DEG. The discontinuation region R2′ may include a plurality of 2DEG unit regions e2′ that are spaced apart from one another.

FIG. 8 is a cross-sectional diagram illustrating a HEMT according to example embodiments.

Referring to FIG. 8, a discontinuation region R3 may be formed in a region of a 2DEG corresponding to a gate electrode G3. The discontinuation region R3 may be formed by a plurality of ion implantation regions 30. The plurality of ion implantation regions 30 may be a region where an impurity is ion-implanted from a region of a channel supply layer CS3 into a region of a channel layer C3 contacting the channel supply layer CS3. The ion-implanted regions 30 may be ion-implanted with an impurity such as argon (Ar) or nitrogen (N). The ion implantation regions 30 may extend to the inside of the channel layer C3. The ion implantation regions 30 may be amorphous regions because the crystallinities of the channel supply layer CS3 and the channel layer C3 are broken by ion implantation of the impurity thus being amorphous. Thus, the 2DEG may not be formed in a portion where the ion implantation regions 30 are formed. Each of a plurality of 2DEG unit regions e3 may be formed between the ion implantation regions 30. The plurality of 2DEG unit regions e3 may have a pattern structure of the discontinuation region R1 as illustrated in FIG. 2A, 2B, or 2C. A gate insulating layer GI3 may be disposed on the channel supply layer CS3 to cover the ion implantation regions 30, and a gate electrode G3 may be formed on the gate insulating layer GI3. However, in example embodiments, the gate insulating layer GI3 may be omitted. Materials and properties of a substrate SUB3, a buffer layer B3, the channel layer C3, the channel supply layer CS3, a source electrode S3, and a drain electrode D3 of the HEMT of FIG. 8 may be the same as or similar to those of the substrate SUB1, the buffer layer B1, the channel layer C1, the channel supply layer CS1, the source electrode S1, and the drain electrode D1 of the HEMT of FIG. 1.

The plurality of ion implantation regions 30 of FIG. 8 may be formed to a different depth. The ion implantation regions 30 may be formed to an interface between the channel layer C3 and the channel supply layer CS3, or to a smaller depth than that of the interface. A case where the ion implantation regions 30 are formed to a smaller depth than that of the interface is illustrated in FIG. 9.

Referring to FIG. 9, ion implantation regions 30′ may be formed to a depth that is smaller than the thickness of the channel supply layer CS3. That is, the ion implantation regions 30′ may not be formed inside the channel layer C3, and may be formed only in the channel supply layer CS3. Even in this case, properties of a region of a 2DEG corresponding to the ion implantation regions 30′ are changed by the ion implantation regions 30′, and thus, a discontinuation region R3′ may be formed in the region of the 2DEG. The discontinuation region R3′ may include a plurality of 2DEG unit regions e3′ that are spaced apart from one another.

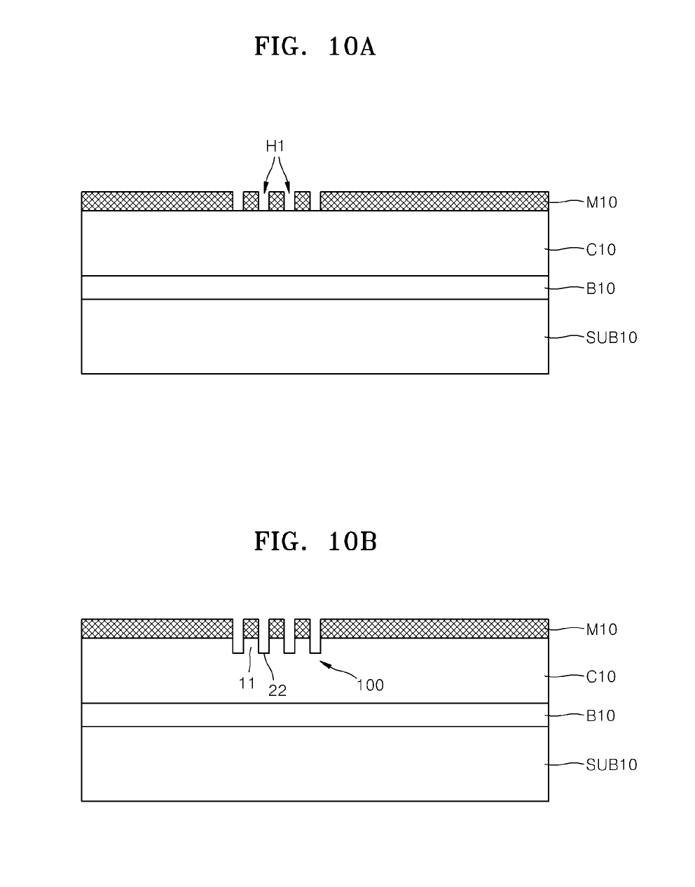

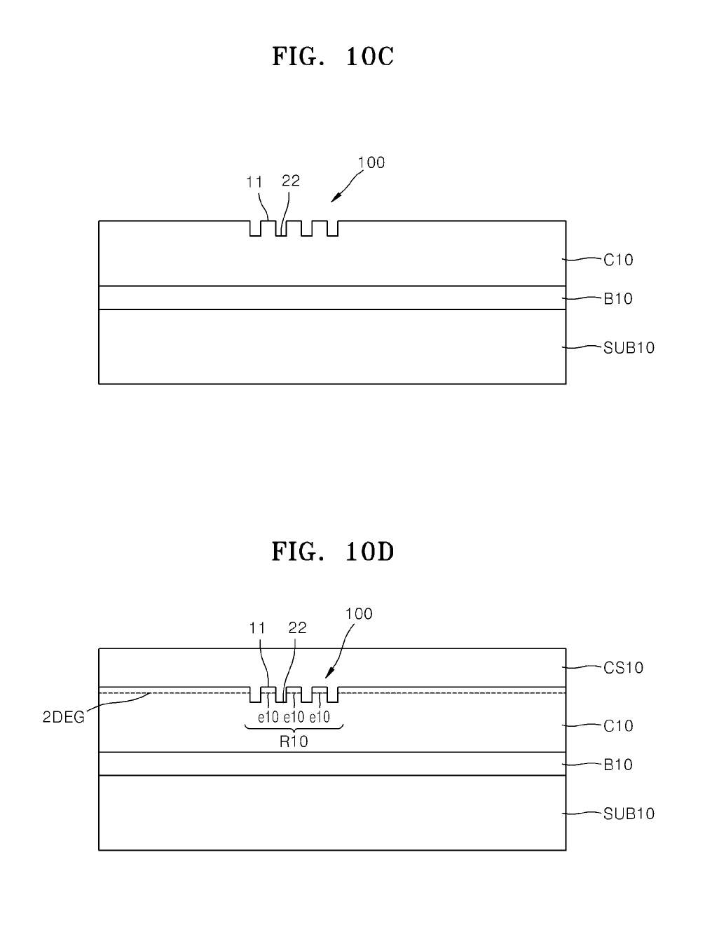

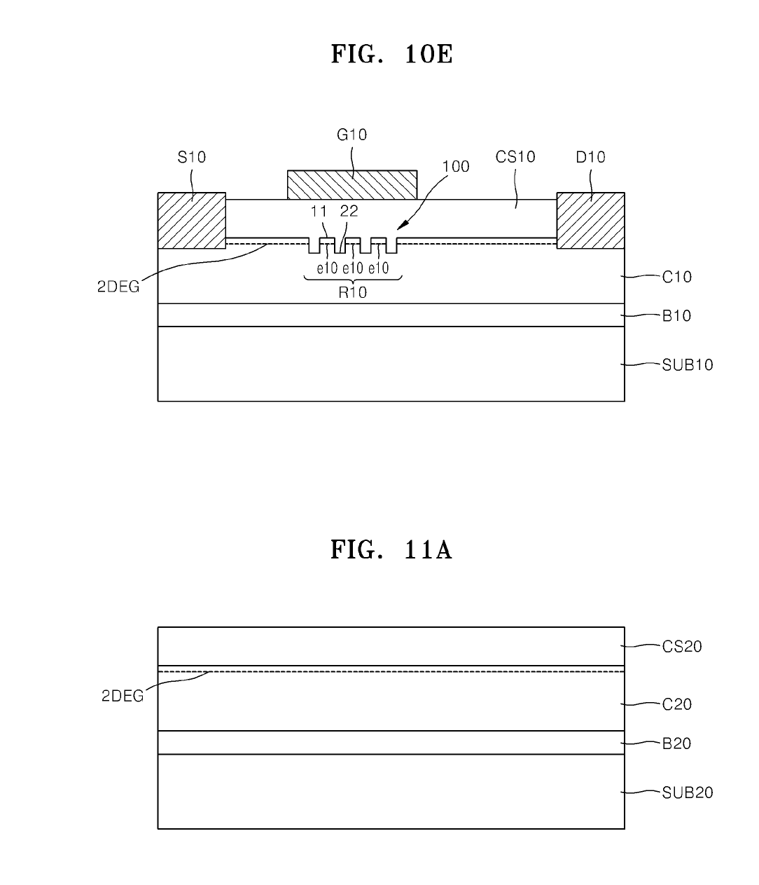

FIGS. 10A through 10E are cross-sectional diagrams sequentially illustrating a method of manufacturing a HEMT, according to example embodiments.

Referring to FIG. 10A, a buffer layer B10 may be formed on a substrate SUB10. The substrate SUB10 may be formed of, for example, sapphire, Si, SiC, GaN, or the like. The buffer layer B10 may reduce differences in lattice constant and thermal expansion coefficient between the substrate SUB10 and a channel layer C10 formed thereon, and thus, may reduce (and/or prevent) deterioration of crystallinity in the channel layer C10. The buffer layer B10 may have a single-layered or multi-layered structure including at least one material selected from nitrides containing at least one of Al, Ga, In, and B. In particular, the buffer layer B10 may have a single-layered or multi-layered structure including at least one of various material selected from AlN, GaN, AlGaN, InGaN, AlInN, and AlGaInN. In some cases, a seed layer (not shown) may be formed between the substrate SUB10 and the buffer layer B10. The seed layer may be a base layer for growing the buffer layer B10. The channel layer C10 may be formed on the buffer layer B10. The channel layer C10 may be a semiconductor layer. The channel layer C10 may include a Group III-V based compound semiconductor. For example, the channel layer C10 may include a GaN-based material (e.g., GaN). In this case, the channel layer C10 may be an undoped GaN layer, but in some cases, may be a GaN layer doped with one or more impurities.

Next, a mask layer M10 may be formed on the channel layer C10. The mask layer M10 may include an opening region H1 that exposes a portion of the channel layer C10. The mask layer M10 may be an etch mask for etching a portion of the channel layer C10. At least a portion of the mask layer M10, e.g., at least a portion thereof including the opening region H1, may be formed as a self-assembled monolayer (SAM) or formed by anodization. At least a portion of the mask layer M10 may also be formed using a nanoimprinting process. The above-listed methods, e.g., the methods of forming at least a portion of the mask layer M10 by using the SAM, anodization, and imprinting, are well known to one of ordinary skill in the art, and thus, a detailed description thereof will not be provided here. Although the mask layer M10 is illustrated in a simplified manner for the convenience of explanation in FIG. 10, in fact, the mask layer M10 may have a more complicated structure than illustrated in FIG. 10A.

Referring to FIG. 10B, an exposed region (a portion of a top surface) of the channel layer C10 may be etched to a certain depth by using the mask layer M10 as an etch mask. As a result, a plurality of depressions 22 may be formed in the channel layer C10. A region of the channel layer C10 that is between the depressions 22 may be referred to as a protrusion 11. An uneven portion 100 may be formed by a plurality of the protrusions 11 and the depressions each formed therebetween.

The resultant structure obtained after the mask layer M10 of FIG. 10B is removed is illustrated in FIG. 10C. Referring to FIG. 10C, the uneven portion 100 is formed in a region of the channel layer C10. As described with reference to FIGS. 10A through 10C, the uneven portion 100 may be formed using one of various methods, for example, a method of using a SAM as an etch mask, a method of using a patterned layer formed by anodization as an etch mask, or a nanoimprinting method. The uneven portion 100 may also be formed using various other methods. Referring to FIG. 10D, a channel supply layer CS10 may be formed on the channel layer C10 with the uneven portion 100 formed therein. The channel supply layer CS10 may be formed of a different semiconductor from that of the channel layer C10. The channel supply layer CS10 may induce a 2DEG in the channel layer C10. The 2DEG may be formed in a portion of the channel layer C10 which is below an interface between the channel layer C10 and the channel supply layer CS10. The channel supply layer CS10 may be formed of a material (semiconductor) having different polarization characteristic and/or energy bandgap and/or lattice constant from that of the channel layer C10. For example, the channel supply layer CS10 may be formed of a material having higher polarizability and/or wider energy bandgap from that of the channel layer C10. For example, the channel supply layer CS10 may have a single-layered or multi-layered structure including at least one material selected from nitrides containing at least one of Al, Ga, In, and B. In particular, the channel supply layer CS10 may have a single-layered or multi-layered structure including at least one of various materials selected from AlGaN, AlInN, InGaN, AlN, AlInGaN, and the like. The channel supply layer CS10 may be an undoped layer, or may be a layer doped with one or more impurities.

A discontinuation region R10 may be formed in a layer of the 2DEG by the uneven portion 100. The discontinuation region R1 may include a plurality of 2DEG unit regions e10 that are spaced apart from each other. Each 2DEG unit region e10 may correspond to the protrusion 11. The plurality of 2DEG unit regions e10 may have a nanoscale structure. For example, each 2DEG unit region e10 may have a width of about tens of nanometers to about hundreds of nanometers. A gap between the 2DEG unit regions e10 may be about several nanometers to about hundreds of nanometers. The width and gap ranges are provided for illustrative purposes only, and the width and gap ranges may vary if desired. For example, the width of the 2DEG unit region e10 may be greater than several hundreds of nanometers, and the gap therebetween may also be greater than several hundreds of nanometers. For example, each 2DEG unit region e10 may have a width of about 10 nm to about 900 nm, about 30 nm to about 800 nm, and/or about 50 nm to about 500 nm, but example embodiments are not limited thereto. For example, a gap between the 2DEG unit regions e10 may be about 5 nm to about 500 nm, and/or about 10 nm to about 300 nm.

The discontinuation region R10 may be a region where the 2DEG is patterned. That is, the discontinuation region R10 may be a patterned 2DEG region. The plurality of 2DEG unit regions e10 may be formed into a dot pattern as illustrated in FIG. 2A, a stripe pattern as illustrated in FIG. 2B, or a staggered pattern as illustrated in FIG. 2C. However, example embodiments are not limited thereto. Referring to FIG. 10E, a gate electrode G10 may be formed on the channel supply layer CS10. The gate electrode G10 may be formed on a portion of the channel supply layer CS10 corresponding to the discontinuation region R10. The gate electrode G10 may be formed of a metal, a metal compound, or the like. A source electrode S10 and a drain electrode D10 may be formed at both sides of the gate electrode G10, both of which are spaced apart from the gate electrode G10. The source and drain electrodes S10 and D10 may be electrically connected to the 2DEG. The source electrode S10 and the drain electrode D10 may be formed on an etched region (recess region) formed by etching (recessing) a portion of each of the channel supply layer CS10 and the channel layer C10. In this case, a depth of the etched region (recess region) may be deeper than that of the 2DEG. Thus, the source and drain electrodes S10 and D10 may directly contact side portions of the 2DEG. However, example embodiments not limited thereto. For example, the source/drain electrodes S10 and D10 may be formed after only the channel supply layer CS10 is partially etched, or may be formed on the channel supply layer CS10 without the etching process. The source electrode S10 may be positioned closer to the gate electrode G10 than the drain electrode D10. That is, a distance between the source electrode S10 and the gate electrode G10 may be less than a distance between the drain electrode D10 and the gate electrode G10, but is not limited thereto. Relative distances between the source electrode S10 and the gate electrode G10 and between the drain electrode D10 and the gate electrode G10 may vary.

The manufacturing method illustrated in FIGS. 10A through 10E may have various modifications. For example, the uneven portion 100 may have various structures and be formed using various methods. In example embodiments, not as described above that the uneven portion 100 is formed by partially etching the channel layer C10, an uneven portion may be formed by forming a plurality of protrusions on the channel layer C10. Through this process, the uneven portion 10′ as illustrated in FIG. 4 may be formed. Also, uneven portions with various shapes may be formed using various other methods.

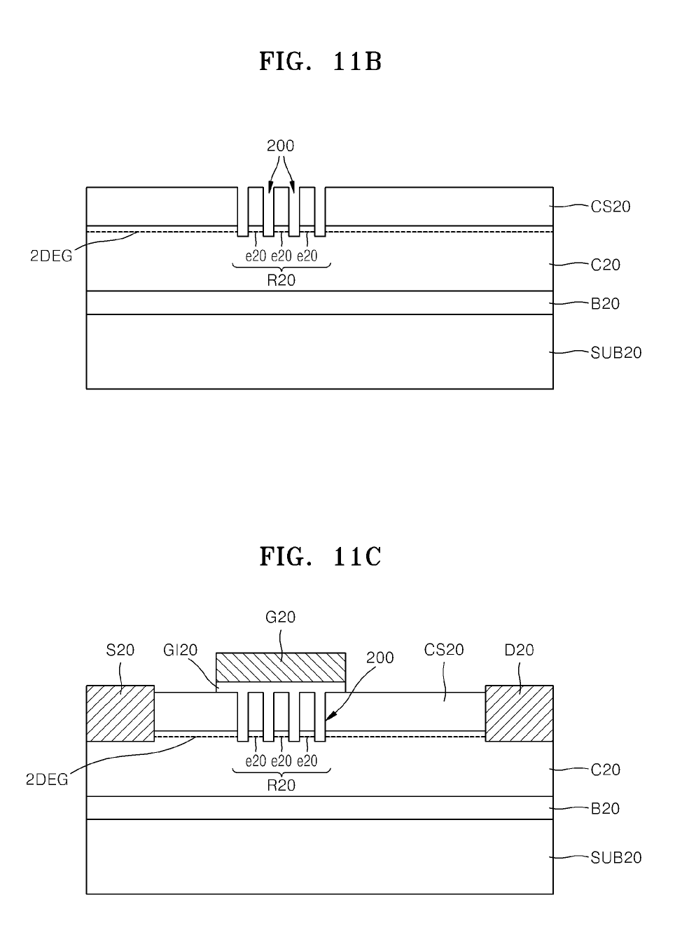

FIGS. 11A through 11C are cross-sectional diagrams sequentially illustrating a method of manufacturing a HEMT, according to example embodiments.

Referring to FIG. 11A, a buffer layer B20 may be formed on a substrate SUB20, and a channel layer C20 may be formed on the buffer layer B20. A channel supply layer CS20 may be formed on the channel layer C20. The channel supply layer CS20 may induce a 2DEG in the channel layer C20. Thus, the 2DEG may be formed in the channel layer C20 due to the channel supply layer CS20. Materials and thicknesses of the substrate SUB20, the buffer layer B20, the channel layer C20, and the channel supply layer CS20 may be the same as or similar to those of the substrate SUB1, the buffer layer B1, the channel layer C1, and the channel supply layer CS1 of the HEMT of FIG. 1.

Referring to FIG. 11B, a plurality of recess regions 200 may be formed in a region of the channel supply layer CS20. The plurality of recess regions 200 may be regions recessed from the channel supply layer CS20 to the channel layer C20. The plurality of recess regions 200 may extend to the inside of the channel layer C20. Therefore, a discontinuation region R20 may be formed in a region of the 2DEG by the plurality of recess regions 200. The discontinuation region R20 may include a plurality of 2DEG unit regions e20 that are spaced apart from one another. Each 2DEG unit region e20 may be formed between the recess regions 200. The plurality of 2DEG unit region e20 may be formed in a dot pattern as illustrated in FIG. 2A, a stripe pattern as illustrated in FIG. 2B, or a staggered pattern as illustrated in FIG. 2C. However, example embodiments are not limited thereto.

Referring to FIG. 11C, a gate electrode G20 may be formed on the channel supply layer CS20 in which the plurality of recess regions 200 are formed. A gate insulating layer GI20 may be formed on the channel supply layer CS20 to cover the plurality of recess regions 200, and then the gate electrode G20 may be formed on the gate insulating layer GI20. In FIG. 11C, the gate insulating layer GI20 is formed on the channel supply layer CS20. In example embodiments, however, the gate insulating layer GI20 may be formed only inside the plurality of recess regions 200, and the gate electrode G20 may be formed on the gate insulating layer GI20 and a region of the channel supply layer CS20 that is around the gate insulating layer GI20.

In another embodiment, the gate insulating layer GI20 may not be formed, and the gate electrode G20 may be directly formed on the channel supply layer CS20. In this case, the plurality of recess regions 200 may not be filled by the gate electrode G20, and be maintained empty (e.g., void). A source electrode S20 and a drain electrode D20 may be formed at both sides of the gate electrode G20, both of which are spaced apart from the gate electrode G20. The source and drain electrodes S20 and D20 may be electrically connected to the 2DEG. The source and drain electrodes S20 and D20 may be formed using the same method as that used to form the source and drain electrodes 510 and D10 of FIG. 10E, and the formation method thereof may be variously modified.

The manufacturing method illustrated in FIGS. 11A through 11C may be variously modified. For example, the recess regions 200 of FIG. 11B may be formed to a different depth. For example, the recess regions 200 may be formed to an interface between the channel layer C20 and the channel supply layer CS20 or to a depth that is shallower than the interface.

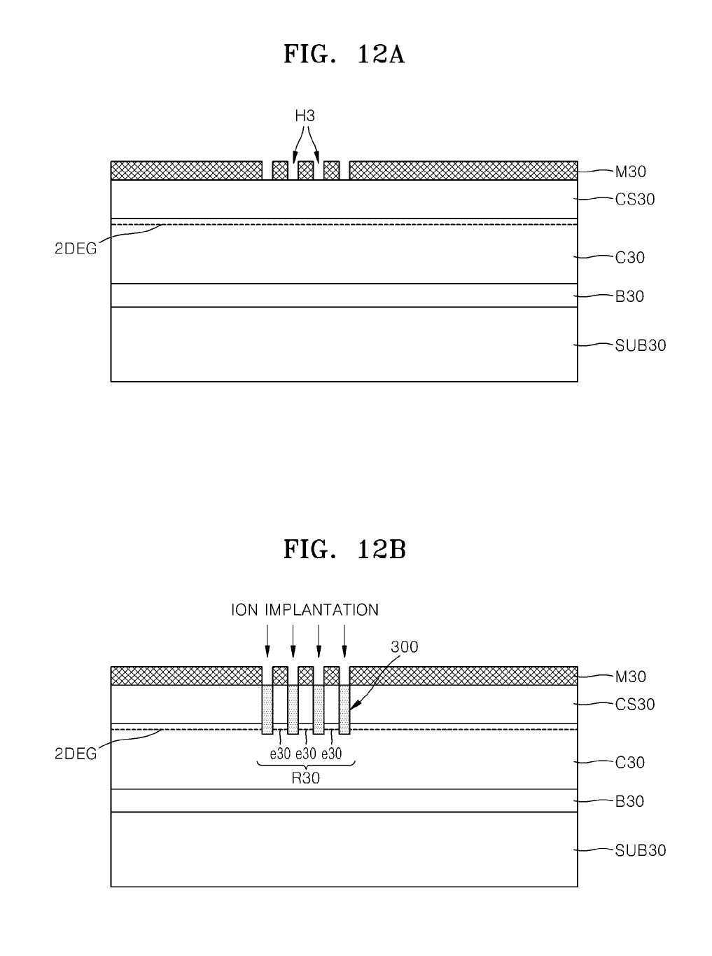

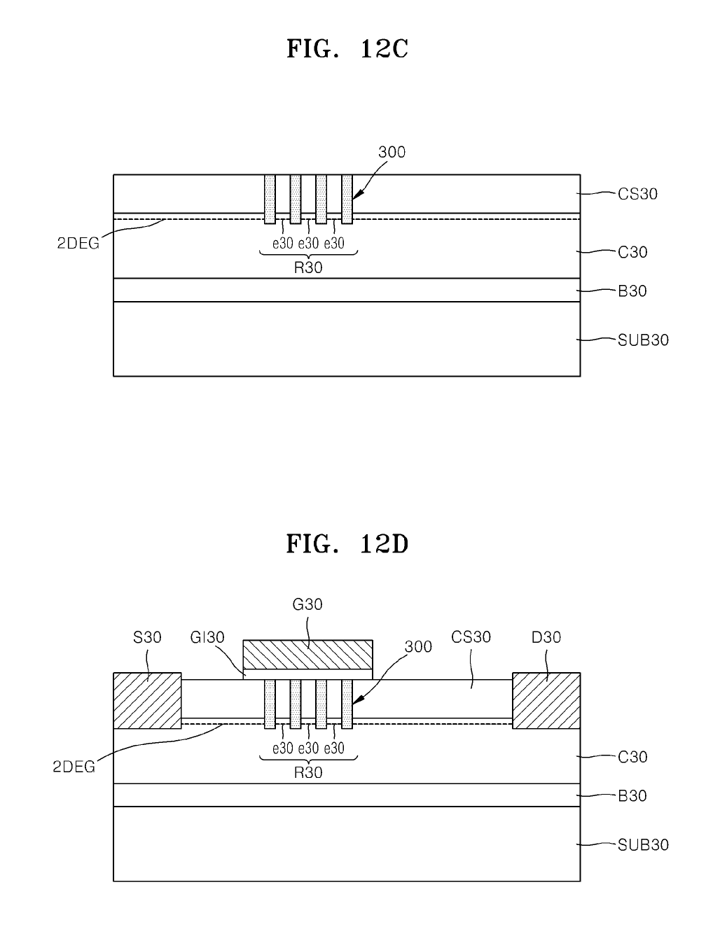

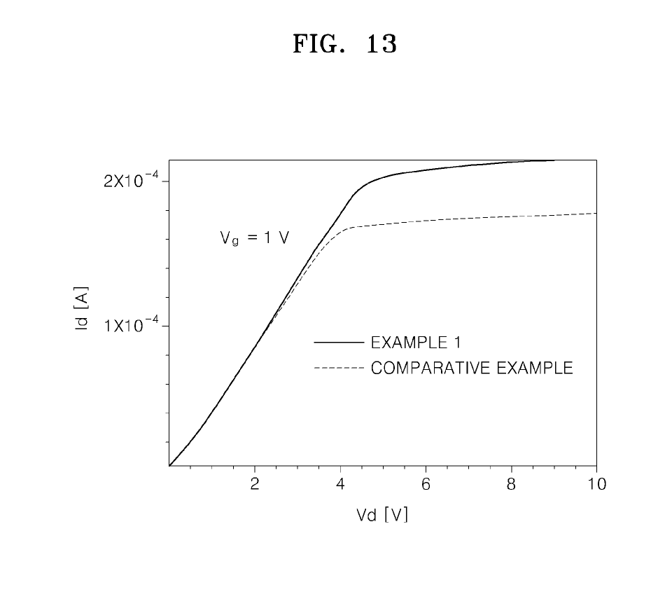

FIGS. 12A through 12D are cross-sectional diagrams sequentially illustrating a method of manufacturing a HEMT, according to example embodiments.

Referring to FIG. 12A, a buffer layer B30 may be formed on a substrate SUB30, and a channel layer C30 may be formed on the buffer layer B30. A channel supply layer CS30 may be formed on the channel layer C30. The channel supply layer CS30 may induce a 2DEG in the channel layer C30. Materials and thicknesses of the substrate SUB30, the buffer layer B30, the channel layer C30, and the channel supply layer CS30 may be the same as or similar to those of the substrate SUB1, the buffer layer B1, the channel layer C1, and the channel supply layer CS1 of the HEMT of FIG. 1. Next, a mask layer M30 may be formed on the channel supply layer CS30. The mask layer M30 may include an opening region H3 that exposes a portion of the channel supply layer CS30. The mask layer M30 may be a mask for ion implantation.

Referring to FIG. 12B, an impurity may be ion-implanted into the exposed region (a portion of a top surface) of the channel supply layer CS30 by using the mask layer M30 as an ion implantation mask. In this regard, the impurity may be argon (Ar) or nitrogen (N). Through the ion implanting process, a plurality of ion implantation regions 300 may be formed. The plurality of ion implantation regions 300 may extend to the inside of the channel layer C30. The ion implantation regions 300 into which the impurity is ion-implanted may have an amorphous structure due to its broken crystallinity. Therefore, a discontinuation region R30 may be formed by the plurality of ion implantation regions 300 in a region where the 2DEG is formed. The discontinuation region R30 may include a plurality of 2DEG unit regions e30 that are spaced apart from one another. Each 2DEG unit region e30 may be formed between the ion implantation regions 300. The 2DEG unit regions e30 may be formed in a dot pattern as illustrated in FIG. 2A, a stripe pattern as illustrated in FIG. 2B, or a staggered pattern as illustrated in FIG. 2C. However, example embodiments are not limited thereto.

A resultant structure obtained after the mask layer M30 of FIG. 12B is removed is illustrated in FIG. 12C. Referring to FIG. 12C, the ion implantation regions 300 extending from the channel supply layer CS30 into the channel layer C30 that contacts the channel supply layer CS30 are formed.

Referring to FIG. 12D, a gate electrode G30 may be formed on a portion of the channel supply layer CS30 corresponding to the discontinuation region R30 to cover the plurality of ion implantation regions 300. After a gate insulating layer GI30 is formed, the gate electrode G30 may be formed on the gate insulating layer GI30. A source electrode S30 and a drain electrode D30 may be formed at both sides of the gate electrode G30, both of which are spaced apart from the gate electrode G30. The source and drain electrodes S30 and D30 may be electrically connected to the 2DEG. The source and drain electrodes S30 and D30 may be formed using the same method as that used to form the source and drain electrodes 510 and D10 of FIG. 10E, and may be formed using other various methods.

The manufacturing method illustrated in FIGS. 12A through 12D may be variously modified. For example, the ion implantation regions 300 of FIG. 12B may be formed to a different depth. For example, the ion implantation regions 300 may be formed to an interface between the channel layer C30 and the channel supply layer CS30 or to a depth that is shallower than the interface.

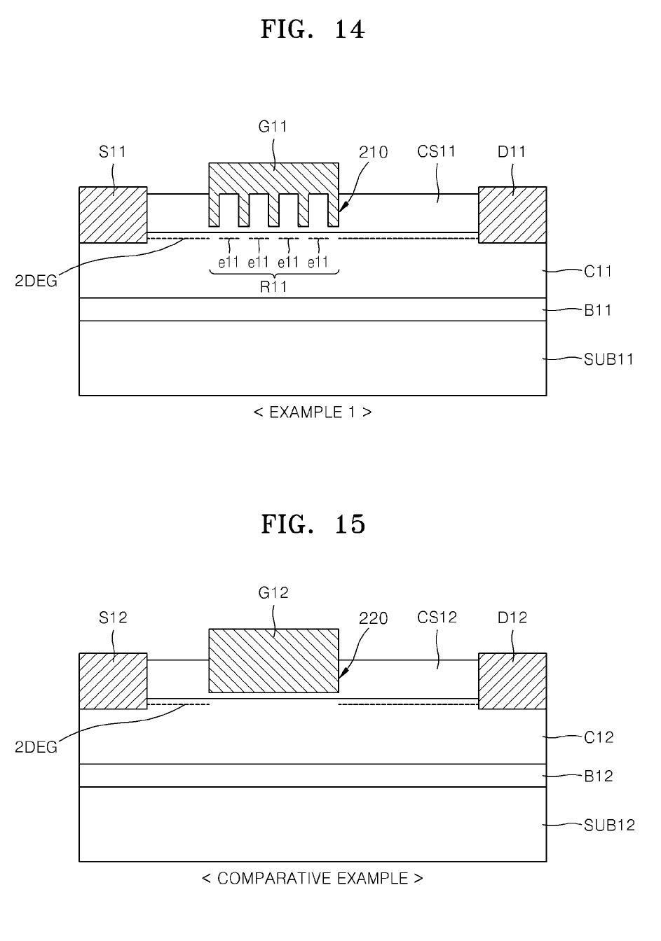

FIG. 13 is a graph showing voltage-current characteristics of a HEMT according to Example 1 and a HEMT that is a Comparative Example. FIG. 14 illustrates a HEMT according to Example 1 in which the voltage-current characteristics are illustrated in FIG. 13, and the HEMT of Comparative Example has a structure as illustrated in FIG. 15. Briefly, the HEMT according to Example 1 in FIG. 14 is a HEMT according to example embodiments that includes a discontinuation region R11 including a plurality of 2DEG unit regions e11 that are spaced apart from each other in a channel region corresponding to a gate electrode G11, and the HEMT of Comparative Example having the structure of FIG. 15 has a structure in which a 2DEG is not present in a channel region corresponding to a gate electrode G12. The structures of HEMTs according to Example 1 and Comparative Example will be described below in more detail with reference to FIGS. 14 and 15.

As shown in FIG. 13, a saturated drain current Id of a HEMT according to Example 1 is approximately 22% higher than that of the HEMT of Comparative Example. This indicates that the HEMT according to Example 1 has a higher on-current and lower on-resistance than that of the HEMT of Comparative Example. On the other hand, it is measured that a threshold voltage of the HEMT according to Example 1 is almost similar to that of the HEMT of Comparative Example. Therefore, in HEMTs according to example embodiments, such as the HEMT according to Example 1 for example, by using the discontinuation region R11, a HEMT having a threshold voltage that is higher than 0 V and a low channel resistance (or low on-resistance) may be obtained. As for the HEMT of Comparative Example, the 2DEG is not formed in the channel region corresponding to the gate electrode G12, and thus, the HEMT may have a high threshold voltage while it has a high channel resistance, which causes a problem of a high on-resistance. In this embodiment, however, a HEMT having a high threshold voltage and a low on-resistance may be manufactured.

Hereinafter, the structures of the HEMTs of Example 1 and Comparative Example of FIG. 13 will be described more fully with reference to FIGS. 14 and 15.

Referring to FIG. 14, the HEMT according to Example 1 is a HEMT according to example embodiments that includes a plurality of recess regions 210 in a channel supply layer CS11 and a discontinuation region R11 formed by the plurality of recess regions 210. The discontinuation region R11 includes the plurality of 2DEG unit regions e11 that are spaced apart from one another. The gate electrode G11 is formed on the channel supply layer CS11 to fill the recess regions 210. The HEMT of FIG. 14 has a similar structure to that of the HEMT according to example embodiments of FIG. 7, but does not include the gate insulating layer G12′ of FIG. 7. In FIG. 14, reference numerals SUB11, B11, C11, S11, and D11 denote a substrate, a buffer layer, a channel layer, a source electrode, and a drain electrode, respectively.

Referring to FIG. 15, the HEMT of Comparative Example includes a single recess region 220 formed in a channel supply layer CS12 and a gate electrode G12 formed in the recess region 220. The 2DEG is not formed in a channel region corresponding to the recess region 220, e.g., a channel region corresponding to the gate electrode G12. That is, the HEMT of Comparative Example does not include the discontinuation region of the HEMT. In this case, as described above, the channel region corresponding to the gate electrode G12 has a high resistance, and thus, may have a high on-resistance. In FIG. 15, reference numerals SUB12, B12, C12, S12, and D12 respectively denote a substrate, a buffer layer, a channel layer, a source electrode, and a drain electrode.

As described above, according to example embodiments, a threshold voltage of a HEMT may be increased by a discontinuation region of a 2DEG that corresponds to a gate electrode. That is, the 2DEG is not formed continuously, and thus, the threshold voltage of the HEMT may increase. The HEMT may be a normally-off device having a threshold voltage of greater than 0 V. Also, the HEMT may be an E-mode device. A plurality of 2DEG unit regions are adjacent to one another in a region of the 2DEG that corresponds to the gate electrode, e.g., the discontinuation region, and thus, the plurality of 2DEG unit regions provides a high electrical conductivity in the discontinuation region when the HEMT is turned on, which results in decreased on-resistance and increased on-current of the HEMT. In other words, when a bias voltage is applied to the gate electrode (turned-on state), electrons are filled between the 2DEG unit regions and flow of a current through the discontinuation region is possible. Here, the 2DEG unit region may act as an excellent electric conductor. Therefore, the on-resistance of the HEMT may decrease, and the on-current of the HEMT may increase. Accordingly, according to example embodiments, a HEMT having a normally-off characteristic and a low channel resistance may be manufactured. That is, a HEMT operating in an E-mode and having a low on-resistance may be manufactured.

HEMTs according to example embodiments, such as those described with reference to FIGS. 1 through 9 and 14 may be, used in a power device, but example embodiments are not limited thereto. HEMTs according to example embodiments may be used for various other applications as well as a power device.

Example embodiments described herein should be considered in a descriptive sense only and not for purposes of limitation. For example, one of ordinary skill in the art would appreciate that structures of the HEMTs of FIGS. 1 through 9 and 14 may be variously modified. For example, various materials other than a GaN-based material may be used for a channel layer and a channel supply layer. In addition, the disposition of the channel layer and the channel supply layer may be reversed. The methods of FIGS. 10A-10E, 11A-11C, and 12A-12D may be variously modified. Further, inventive concepts described herein may be applied to a semiconductor device, other than the HEMT.

While some example embodiments have been particularly shown and described, it will be understood by one of ordinary skill in the art that variations in form and detail may be made therein without departing from the spirit and scope of the claims. Descriptions of features or aspects within each embodiment should typically be considered as available for other similar features or aspects in other embodiments.

What is claimed is:

1. A high electron mobility transistor (HEMT) comprising:
a first semiconductor layer;
a second semiconductor layer on the first semiconductor layer,
the second semiconductor layer being configured to induce a 2-dimensional electron gas (2DEG) in the first semiconductor layer;
a gate corresponding to a discontinuation region of the first semiconductor layer in which a plurality of 2DEG unit regions are spaced apart from one another; and
a source and a drain spaced apart from the gate,
the source and drain electrically connected to the 2DEG.

2. The HEMT of claim 1, wherein the discontinuation region of the first semiconductor layer is defined by an uneven portion in the first semiconductor layer that is under the gate.

3. The HEMT of claim 2, wherein
the uneven portion is defined by a plurality of protrusions and depressions formed between the protrusions along an upper surface of the first semiconductor layer, and
the second semiconductor layer covers the plurality of protrusions and the plurality of depressions.

4. The HEMT of claim 3, wherein the second semiconductor layer is configured to induce the plurality of 2DEG unit regions in the plurality of protrusions.

5. The HEMT of claim 3, wherein the second semiconductor layer is configured to induce the plurality of 2DEG unit regions in the first semiconductor layer corresponding to the plurality of depressions.

6. The HEMT of claim 1, wherein the discontinuation region of the first semiconductor layer is defined by a plurality of recess regions formed in the second semiconductor layer corresponding to the gate.

7. The HEMT of claim 6, wherein the plurality of recess regions in the second semiconductor layer extend into the first semiconductor layer.

8. The HEMT of claim 6, wherein
the plurality of recess regions in the second semiconductor layer extend to an interface between the first and second semiconductor layers, or
the plurality of recess regions in the second semiconductor layer extend to a depth that is shallower than the interface between the first and second semiconductor layers.

9. The HEMT of claim 6, further comprising:
an insulating layer in the plurality of recess regions in the second semiconductor layer,
wherein the gate is on the insulating layer.

10. The HEMT of claim 1, wherein the discontinuation region of the first semiconductor layer is defined by a plurality of ion implantation regions formed in the second semiconductor layer corresponding to the gate.

11. The HEMT of claim 10, wherein the plurality of ion implantation regions extend inside the first semiconductor layer.

12. The HEMT of claim 10, wherein
the plurality of ion implantation regions extend to an interface between the first and second semiconductor layers, or
the plurality of ion implantation regions extend to a depth of the second semiconductor layer that is shallower than the interface between the first and second semiconductor layers.

13. The HEMT of claim 10, wherein the plurality of ion implantation regions are amorphous regions.

14. The HEMT of claim 1, wherein the second semiconductor layer is a contiguous layer.

15. The HEMT of claim 1, wherein the plurality of 2DEG unit regions are formed in a dot pattern.

16. The HEMT of claim 1, wherein the plurality of 2DEG unit regions are formed in a stripe pattern.

17. The HEMT of claim 1, wherein each of the plurality of 2DEG unit regions has a width from about tens of nanometers to about hundreds of nanometers.

18. The HEMT of claim 1, wherein a gap between the plurality of 2DEG unit regions is in a range of about several nanometers to about hundreds of nanometers.

19. The HEMT of claim 1, wherein the first semiconductor layer contains a gallium nitride (GaN)-based material.

20. The HEMT of claim 1, wherein
the second semiconductor layer includes one of a single-layered structure and a multi-layered structure, and
the second semiconductor layer includes a nitride that contains at least one of aluminum (Al), gallium (Ga), indium (In), and boron (B).

21. The HEMT of claim 1, wherein the HEMT is configured to operate as a normally-off device.

22. A method of manufacturing a high electron mobility transistor (HEMT), the method comprising:
forming a first semiconductor layer;
forming an uneven portion in the first semiconductor layer for defining a discontinuation region of the first semiconductor layer;
forming a second semiconductor layer on the first semiconductor layer,
the second semiconductor layer being configured to induce a 2DEG in the first semiconductor layer and a plurality of 2DEG unit regions that are spaced apart from one another in the discontinuation region of the first semiconductor layer;
forming a gate on the second semiconductor layer and the discontinuation region of the first semiconductor layer; and
forming a source and a drain that are spaced apart from the gate.

23. The method of claim 22, wherein the forming the uneven portion of includes forming a self-assembled monolayer (SAM) as an etch mask on the first semiconductor layer.

24. The method of claim 22, wherein the forming the uneven portion includes forming an etch mask obtained by anodization on the first semiconductor layer.

25. The method of claim 22, wherein the forming the uneven portion includes forming an etch mask on the first semiconductor layer by a nanoimprinting process.

26. The method of claim 22, the plurality of 2DEG unit regions are formed in one of a dot pattern and a stripe pattern.

27. The method of claim 22, wherein
the first semiconductor layer contains a GaN-based material,
the second semiconductor layer includes one of a single-layered structure and a multi-layered structure, and
the second semiconductor layer contains a nitride that includes at least one of Al, Ga, In, and B.

28. A method of manufacturing a high electron mobility transistor (HEMT), the method comprising;
forming a first semiconductor layer;
forming a second semiconductor layer on the first semiconductor layer,
the second semiconductor layer being configured to induce a 2DEG in the first semiconductor layer;
forming a plurality of recess regions recessed from a region of the second semiconductor layer to a region of the first semiconductor layer,
the recess regions forming a discontinuation region in the first semiconductor layer where a plurality of 2DEG unit regions are spaced apart from one another;
forming a gate on the second semiconductor layer and the discontinuation region of the first semiconductor layer; and
forming a source and a drain that are spaced apart from the gate.

29. The method of claim 28, further comprising:
forming an insulating layer on the second semiconductor layer to fill the plurality of recess regions, wherein
the forming the gate includes forming the gate on the insulating layer.

30. The method of claim 28, wherein the plurality of 2DEG unit regions are formed in one of a dot pattern and a stripe pattern.

31. The method of claim 28, wherein
the first semiconductor layer contains a GaN-based material,
the second semiconductor layer includes one of a single-layered structure and a multi-layered structure, and
the second semiconductor layer contains a nitride that includes at least one of Al, Ga, In, and B.

32. A method of manufacturing a high electron mobility transistor (HEMT), the method comprising:
forming a first semiconductor layer;
forming a second semiconductor layer on the first semiconductor layer,
the second semiconductor layer being configured to induce a 2DEG in the first semiconductor layer;
forming a plurality of ion implantation regions extending from a region of the second semiconductor layer to a region of the first semiconductor layer,
the plurality of ion implantation regions forming a discontinuation region in the first semiconductor layer where a plurality of 2DEG unit regions are spaced apart from one another;
forming a gate on the second semiconductor layer and the discontinuation region of the first semiconductor layer; and
forming a source and a drain that are spaced apart from the gate.

33. The method of claim 32, wherein the plurality of ion implantation regions are amorphous regions.

34. The method of claim 32, wherein the plurality of 2DEG unit regions are formed in one of a dot pattern and a stripe pattern.

35. The method of claim 32, wherein
the first semiconductor layer contains a GaN-based material, and the second semiconductor layer includes one of a single-layered structure and a multi-layered structure, and
the second semiconductor layer contains a nitride that includes at least one of Al, Ga, In, and B.

36. A high electron mobility transistor (HEMT) comprising:
a first semiconductor layer;
a source, a gate, and a drain spaced apart on the first semiconductor layer; and
a second semiconductor layer between the gate and the first semiconductor layer,
the second semiconductor layer being a contiguous layer having a different polarization than a polarization of the first semiconductor layer, and
the second semiconductor layer including one of a plurality of openings defined by the second semiconductor layer, a plurality of grooves defined by the second semiconductor layer, and a plurality of ion implant regions between the gate and the first semiconductor layer, and
the second semiconductor layer being configured to induce a plurality of 2DEG unit regions in the first semiconductor layer that are spaced apart from each other.

37. The HEMT of claim 36, wherein
the second semiconductor layer includes the plurality of openings, and
the plurality of openings defined by the second semiconductor layer expose a plurality of portions of the first semiconductor layer that are between the plurality of 2DEG unit regions of the first semiconductor layer from a plan view.

38. The HEMT of claim 36, wherein
an uneven portion of the first semiconductor layer defines a plurality of protrusions and depressions along an upper surface of the first semiconductor layer, and
the second semiconductor layer is between the gate and the uneven portion of the first semiconductor layer.

39. The HEMT of claim 36, wherein the second semiconductor layer includes the plurality of ion implant regions.

40. The HEMT of claim 36, wherein
the plurality of 2DEG unit regions are formed in one of a dot pattern and a stripe pattern,
the first semiconductor layer contains a GaN-based material, and
the second semiconductor layer includes one of a single-layered structure and a multi-layered structure, and
the second semiconductor layer contains a nitride that includes at least one of Al, Ga, In, and B.
